(19) United States
(12) Patent Application Publication
(10) Pub. No.: US 2022/0244644 A1
(43) Pub. Date: Aug. 4, 2022

(54) A Method of Manufacturing a Transparent Conductive Film

(71) Applicant: AGFA-GEVAERT NV, Mortsel (BE)

(72) Inventors: Matthew Friskey, Mortsel (BE); Karl Van Den Bossche, Mortsel (BE); Peter Willaert, Mortsel (BE); Fernando Cortes Salazar, Mortsel (BE)

(73) Assignee: AGFA-GEVAERT NV, Mortsel (BE)

(21) Appl. No.: 17/626,570

(22) PCT Filed: Jun. 25, 2020
(86) PCT No.: PCT/EP2020/067860

§ 371 Date: Jan. 12, 2022

(30) Foreign Application Priority Data
Jul. 16, 2019 (EP) 19186427.1

(51) Int. Cl. G03F 7/06; H01B 5/14; H01B 1/22

(52) U.S. Cl. CPC G03F 7/066; H01B 1/22; H01B 5/14

(57) ABSTRACT

A method of preparing a transparent conductive film (100) comprising the steps of: —applying a nano-silver composition on a substrate thereby forming a nano-silver coating (20) on the substrate (10), —imagewise exposing the nano-silver coating with Near Infrared (NIR) radiation (40) thereby forming exposed and non-exposed areas, and —removing (70) the non-exposed areas of the nano-silver coating.

### FIELD OF THE INVENTION

The invention relates to a method of preparing a transparent conductive films including silver grids.

### BACKGROUND OF THE INVENTION

Transparent conductive films (TCFs) are used as transparent electrodes in the manufacturing of touch screens, LCDs, cover electrodes for solar cells and organic light-emitting diodes.

For the past decades, Indium Tin Oxide (ITO) has been the dominant material used for such transparent TCF applications. However, there is a need to find alternatives that offer lower materials and patterning costs, greater flexibility, better opto-electronic performance and have no supply constraints like exists with Indium.

WO2003/106573 (Cima NanoTech) disclose a silver nanoparticle technology that self-assembles into a random mesh-like network pattern on substrates is disclosed in for example WO2003/106573. WO2007/022226 and WO2008/046058 (Cambrios) disclose TCFs based on electrically conductive nanowires in an optically clear matrix. TCFs based on carbon nanotubes have also been disclosed

US20140198264 disclose a TCF comprising a metal mesh made of conductive material containing metal in a trench. This method requires a nanoimprinting step.

The UV curable silver paste from Toray (Raybrid™) is also used to manufacture TCFs. A silver pattern consisting of fine lines is prepared by exposing a coating of the silver paste through a mask with UV light, removing the non-exposed parts of the coating and sintering the resulting silver pattern to obtain a transparent conductive film consisting of a silver mesh. This method requires a lot of process steps and consumes a lot of chemistry, including expensive silver.

EP-A 2720086 (NANO AND ADVANCED MATERIALS) disclose a method of fabricating a transparent conductive film wherein a coating comprising silver nanowires is exposed with a high energy flash light source through a mask to anneal and pattern the coating. No post treatment is carried out after the exposure step.

EP-A 2671927 (Agfa Gevaert) discloses a metallic nanoparticle dispersion, for example a silver inkjet ink, comprising a specific dispersion medium, for example 2-pyrrolidone, resulting in a more stable dispersion without using a polymeric dispersant.

EP-A 3037161 (Agfa Gevaert) discloses a metallic nanoparticle dispersion comprising silver nanoparticles, a liquid carrier and specific dispersion stabilizing compounds.

### SUMMARY OF THE INVENTION

It is an object of the present invention to provide a cost effective method of preparing a transparent conductive film.

This object is realized by the method as defined in claim 1.

Further advantages and embodiments of the present invention will become apparent from the following description and the dependent claims.

### BRIEF DESCRIPTION OF THE DRAWINGS

FIG. 1 shows schematically an embodiment of the method according to the present invention.

FIG. 2 shows schematically an optical mask used in the examples.

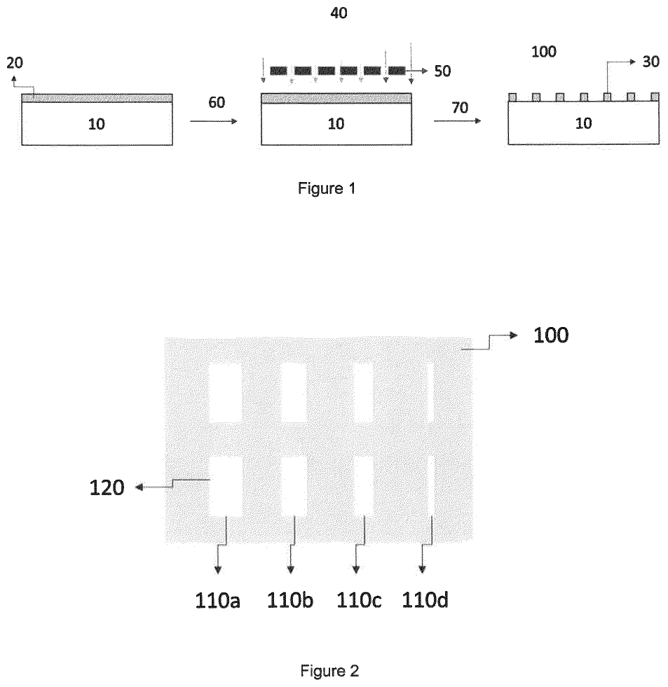

### DETAILED DESCRIPTION OF THE INVENTION

### Definitions

The terms polymeric support and foil, as used herein, mean a self-supporting polymer-based sheet, which may be associated with one or more adhesion layers, e.g. subbing layers. Supports and foils are usually manufactured through extrusion.

The term layer as used herein, is considered not to be self-supporting and is manufactured by coating or spraying it on a (polymeric) support or foil.

PET is an abbreviation for polyethylene terephthalate.

The term alkyl means all variants possible for each number of carbon atoms in the alkyl group i.e. methyl, ethyl, for three carbon atoms: n-propyl and isopropyl; for four carbon atoms: n-butyl, isobutyl and tertiary-butyl; for five carbon atoms: n-pentyl, 1,1-dimethyl-propyl, 2,2-dimethylpropyl and 2-methyl-butyl etc.

Unless otherwise specified a substituted or unsubstituted alkyl group is preferably a C₁ to C₆-alkyl group.

Unless otherwise specified a substituted or unsubstituted alkenyl group is preferably a C₂ to C₆-alkenyl group.

Unless otherwise specified a substituted or unsubstituted alkynyl group is preferably a C₂ to C₆-alkynyl group.

Unless otherwise specified a substituted or unsubstituted alkaryl group is preferably a phenyl group or a naphthyl group including one, two, three or more C₁ to C₆-alkyl groups.

Unless otherwise specified a substituted or unsubstituted aralkyl group is preferably a C₁ to C₆-alkyl group including an aryl group, preferably a phenyl group or naphthyl group.

Unless otherwise specified a substituted or unsubstituted aryl group is preferably a substituted or unsubstituted phenyl group or naphthyl group.

A cyclic group includes at least one ring structure and may be a monocyclic- or polycyclic group, meaning one or more rings fused together.

A heterocyclic group is a cyclic group that has atoms of at least two different elements as members of its ring(s). The counterparts of heterocyclic groups are homocyclic groups, the ring structures of which are made of carbon only. Unless otherwise specified a substituted or unsubstituted heterocyclic group is preferably a five- or six-membered ring substituted by one, two, three or four heteroatoms, preferably selected from oxygen atoms, nitrogen atoms, sulphur atoms, selenium atoms or combinations thereof.

An alicyclic group is a non-aromatic homocyclic group wherein the ring atoms consist of carbon atoms.

The term heteroaryl group means a monocyclic- or polycyclic aromatic ring comprising carbon atoms and one or more heteroatoms in the ring structure, preferably, 1 to 4 heteroatoms, independently selected from nitrogen, oxygen, selenium and sulphur. Preferred examples of heteroaryl groups include, but are not limited to, pyridinyl, pyridazinyl, pyrimidyl, pyrazyl, triazinyl, pyrrolyl, pyrazolyl, imidazolyl, (1,2,3)- and (1,2,4)-triazolyl, pyrazinyl, pyrimidinyl, tetrazolyl, furyl, thienyl, isoxazolyl, thiazolyl, isoxazolyl, and oxazolyl. A heteroaryl group can be unsubstituted or substituted with one, two or more suitable substituents. Preferably, a heteroaryl group is a monocyclic ring, wherein the ring comprises 1 to 5 carbon atoms and 1 to 4 heteroatoms.

The term substituted, in e.g. substituted alkyl group means that the alkyl group may be substituted by other atoms than the atoms normally present in such a group, i.e. carbon and hydrogen. For example, a substituted alkyl group may include a halogen atom or a thiol group. An unsubstituted alkyl group contains only carbon and hydrogen atoms.

Unless otherwise specified a substituted alkyl group, a substituted alkenyl group, a substituted alkynyl group, a substituted aralkyl group, a substituted alkaryl group, a substituted aryl, a substituted heteroaryl and a substituted heterocyclic group are preferably substituted by one or more substituents selected from the group consisting of methyl, ethyl, n-propyl, isopropyl, n-butyl, 1-isobutyl, 2-isobutyl and tertiary-butyl, ester, amide, ether, thioether, ketone, aldehyde, sulfoxide, sulfone, sulfonate ester, sulphonamide, —Cl, —Br, —I, —OH, —SH, —CN and —NO₂.

### Method of Preparing a Conductive Silver Pattern

The method of preparing a transparent conductive film (100) according to the present invention comprises the steps of:
applying a silver composition on a substrate thereby forming a nano-silver coating (20) on the substrate (10),
imagewise exposing the silver coating with Near Infrared (NIR) radiation (40) thereby forming exposed and non-exposed areas, and
removing (70) the non-exposed areas of the nano-silver coating.

The method preferably comprises a drying step wherein the silver coating is dried before imagewise exposing it to NIR radiation.

The method may further comprise a thermal treatment after removing the non-exposed areas of the silver coating.

### Silver Coating

In the method according to the present invention, a silver composition is applied on a substrate thereby forming a nano-silver coating (20) on the substrate (10).

A silver composition referred to herein means a composition comprising silver particles. The silver composition preferably comprises silver nano-particles. A preferred silver composition is described below.

The silver composition may be provided onto the substrate by any conventional coating technique, such as dip coating, knife coating, extrusion coating, spin coating, spray coating, slide hopper coating and curtain coating.

The nano-silver composition may also be provided onto a support by any printing method such as intaglio printing, screen printing, flexographic printing, offset printing, inkjet printing, rotogravure printing, etc.

The silver amount of the dried silver coating is preferably between 0.5 and 50 g/m², more preferably between 1 and 10 g/m², most preferably between 2 and 5 g/m².

### NIR Patterning

The silver coating is imagewise exposed using NIR radiation. NIR radiation induces sintering of the silver particles. During this sintering step, also referred to as curing step, solvents evaporate and the silver particles sinter together. Once a continuous percolating network is formed between the silver particles, the conductivity of the pattern increases.

It has now been observed that the non-exposed areas of the silver coating may be removed, for example with a solvent, while the exposed areas remain substantially intact. In this way, patterning of the silver coating becomes possible.

NIR radiation typically has a wavelength between 780 and 2500 nm.

The silver particles in the coating may act as absorber for the NIR radiation. To increase the absorption of the NIR radiation, NIR absorbing compounds may be added to the silver coating. Such NIR absorbing compounds may be NIR absorbing pigments, such as carbon black or TiO₂, or NIR absorbing dyes, such as cyanine dyes.

Adding NIR absorbers to the silver pattern may however negatively influence the sintering process by disturbing the percolating network of the silver particles or the stability of the dispersion.

NIR lamp systems are commercially available from suppliers such as for example ADPHOS and can be provided in different lamp arrangements (e.g. 1 to 6 bulbs) and with lamp powers ranging from 1.2 to 8.3 kW. NIR lamps allow sintering of silver nanoparticle based inks in a few seconds.

When NIR lamp systems are used, the imagewise exposure is preferably carried out through a mask (50).

The mask is substantially non-transparent for NIR radiation, except for the pattern that has to be realized.

According to another preferred embodiment, imagewise exposure is realized with a NIR laser. The pattern is then realized with the NIR laser without the need for using a mask.

A preferred NIR laser is an optically pumped semiconductor laser. Optically pumped semiconductor lasers have the advantage of unique wavelength flexibility, different from any other solid-state based laser. The output wavelength can be set anywhere between about 920 nm and about 1150 nm. This allows a perfect match between the laser emission wavelength and the absorption maximum of NIR absorbing compounds present in the silver coating.

A preferred pulsed laser is a solid state Q-switched laser. Q-switching is a technique by which a laser can be made to produce a pulsed output beam. The technique allows the production of light pulses with extremely high peak power, much higher than would be produced by the same laser if it were operating in a continuous wave (constant output) mode, Q-switching leads to much lower pulse repetition rates, much higher pulse energies, and much longer pulse durations.

NIR patterning may also be carried out using a so-called Spatial Light Modulator (SLM) as disclosed in WO2012/044400 (Vardex Laser Solutions).

The NIR exposure is preferably optimized to ensure maximal removal of the non-exposed areas while the exposed areas remain substantially intact.

### Removal of the Non-Exposed Areas

After NIR exposure, the non-exposed areas of the silver coating are removed to produce the silver pattern.

The non-exposed areas are preferably removed with a solvent.

The non-exposed areas are preferably removed by rubbing the exposed and non-exposed areas of the silver coating with a solvent or a mixture of solvents.

The solvent is selected from the group consisting of water, propylene carbonate, and a phenoxyethanol/2-pyrolidone mixture.

The amount of silver in the exposed areas after removal of the non-exposed areas is preferably at least 60%, more preferably at least 75% most preferably at least 85% relative to the amount of silver before removal of the non-exposed areas.

The amount of silver in the non-exposed areas after removal of the non-exposed areas is preferably less than 40%, more preferably less than 25%, most preferably less than 10% relative to the amount of silver before removal on the non-exposed areas. In a particular preferred embodiment, substantially no silver is present in the non-exposed areas after removal of these non-exposed areas.

### Drying

The method according to the present invention preferably includes a drying step wherein the applied silver coating is dried. The drying step is preferably carried out before the patterning step and is therefore also referred to as a pre-drying step.

In the drying step the silver coating is dried by applying heat to the coating.

Pre-drying is preferably carried out in an oven during 15 to 30 minutes at a temperature between 40 and 100° C., more preferably during 20 to 25 minutes at a temperature between 60 and 80°.

### Thermal Treatment

The method according to the present invention may also include a thermal treatment step after removal of the non-exposed areas.

Such a thermal treatment may further increase the conductivity of the silver pattern and/or the adhesion of the silver pattern to the substrate.

The thermal treatment is preferably carried out during 15 to 60 minutes at a temperature between 130 and 180° C., more preferably during 20 to 40 minutes at a temperature between 150 and 16° C.

When the thermal treatment is carried out at a relatively high Relative Humidity (RH) then high conductivities may be obtained even at lower temperatures. When the relative humidity is at least 50%, preferably at least 60%, more preferably at least 70%, most preferably at least 80% then the temperature is preferably at least 60° C., more preferably at least 70° C., most preferably at least 80° C.

A thermal treatment at lower temperatures enables the use of substrates that do not withstand high temperatures, such as for example PVC substrates.

### Silver Composition

The silver ink comprises silver particles, preferably silver nano-particles. Silver nanoparticles have an average particle size or average particle diameter, measured with Transmission Electron Microscopy, of less than 150 nm, preferably less than 100 nm, more preferably less than 50 nm, most preferably less than 30 nm.

Silver particles and silver nano-particles as used herein include at least 90 wt % of silver, preferably at least 95 wt %, most preferably at least 99 wt %, particularly preferred 100 wt % silver, relative to the total weight of the particles or nano-particles. This means that silver particles or nano-particles as used herein are not silver halide or silver nitrate particles as disclosed for example in US2010/247870.

The amount of silver nanoparticles in the ink is preferably at least 5 wt %, more preferably at least 10 wt %, most preferably at least 15 wt %, particularly preferred at least 20 wt %, relative to the total weight of the silver ink.

The silver nanoparticles are preferably prepared by the method disclosed in EP-A 2671927, paragraphs [0044] to [0053] and the examples.

The silver ink may however also comprise silver flakes or silver nanowires.

As described above, the silver composition may be applied on a substrate by coating or printing. The silver composition is preferably optimized, for example its viscosity, according to the application method used. The silver ink may be a flexographic ink, an offset ink, a rotogravure ink, a screen ink, or an inkjet ink.

The silver ink may further comprise a dispersion stabilizing compound (DSC), a liquid carrier, a polymeric dispersant and other additives to further optimize its properties.

### Dispersion Stabilizing Compound

The silver composition preferably comprises a dispersion-stabilizing compound (DSC) according to Formulae I, II, III or IV,

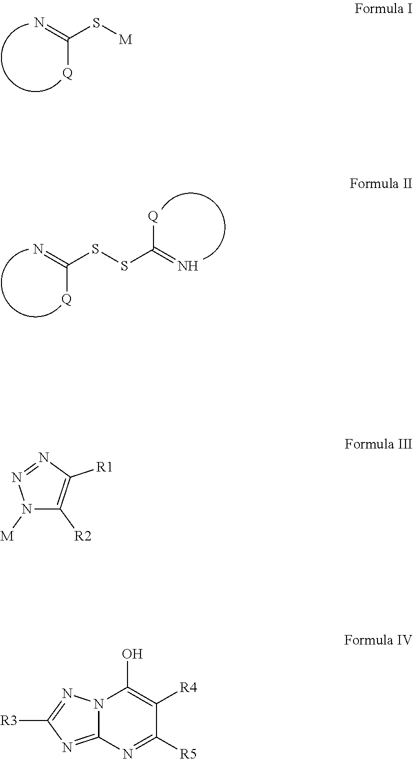

wherein

Q represents the necessary atoms to form a substituted or unsubstituted five or six membered heteroaromatic ring;

M is selected from the group consisting of hydrogen, a monovalent cationic group and an acyl group;

R1 and R2 are independently selected from the group consisting of a hydrogen, a substituted or unsubstituted alkyl group, a substituted or unsubstituted alkenyl group, a substituted or unsubstituted alkynyl group, a substituted or unsubstituted alkaryl group, a substituted or unsubstituted aralkyl group, a substituted or unsubstituted aryl or heteroaryl group, a hydroxyl group, a thioether, an ether, an ester, an amide, an amine, a halogen, a ketone and an aldehyde;

R1 and R2 may represent the necessary atoms to form a five to seven membered ring;

R3 to R5 are independently selected from the group consisting of a hydrogen, a substituted or unsubstituted alkyl group, a substituted or unsubstituted alkenyl group, a substituted or unsubstituted alkynyl group, a substituted or unsubstituted alkaryl group, a substituted or unsubstituted aralkyl group, a substituted or unsubstituted aryl or heteroaryl group, a hydroxyl group, a thiol, a thioether, a sulfone, a sulfoxide, an ether, an ester, an amide, an amine, a halogen, a ketone, an aldehyde, a nitrile and a nitro group;

R4 and R5 may represent the necessary atoms to form a five to seven membered ring.

A particular preferred compound A that decomposes exothermally during the sintering step is has a chemical structure according to Formula I,

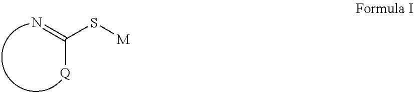

wherein

M is selected from the group consisting of hydrogen, a monovalent cationic group and an acyl group; and

Q represents the necessary atoms to form a five membered heteroaromatic ring.

M in Formula I is preferably a hydrogen.

Q is preferably a five membered heteroaromatic ring selected from the group consisting of an imidazole; a benzimidazole; a thiazole; a benzothiazole; an oxazole; a benzoxazole; a 1,2,3-triazole; a 1,2,4-triazole; an oxadiazole; a thiadiazole and a tetrazole.

Q is more preferably a tetrazole.

Some examples of dispersion-stabilizing compounds are shown in Table 1,

TABLE 1

| DSC | Chemical Formula |
|---|---|
| A-01 | 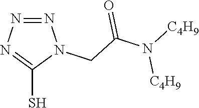 |
| A-02 | 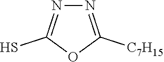 |
| A-03 | 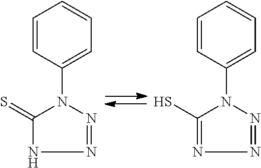 [SMILES: S=c1[nH]nnn1-c1ccccc1 ; Sc1nnnn1-c1ccccc1] |
| A-04 | 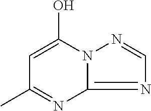 |
| A-05 | 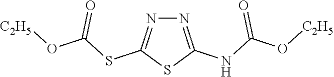 [SMILES: CCOC(=O)Nc1nnc(SC(=O)OCC)s1] |
| A-06 | 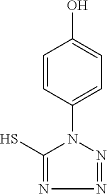 [SMILES: Oc1ccc(-n2nnnc2S)cc1] |
| A-07 | 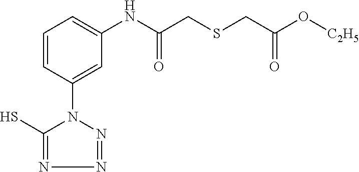 [SMILES: CCOC(=O)CSCC(=O)Nc1cccc(-n2nnnc2S)c1] |
| A-08 | 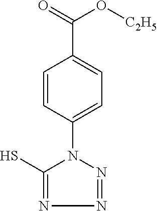 [SMILES: CCOC(=O)c1ccc(-n2nnnc2S)cc1] |
| A-09 | 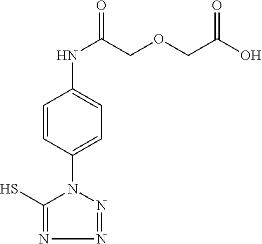 [SMILES: O=C(O)COCC(=O)Nc1ccc(-n2nnnc2S)cc1] |
| A-10 | 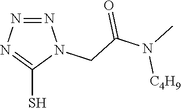 |
| A-11 | 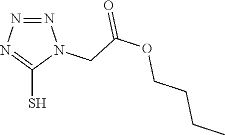 |
| A-12 | 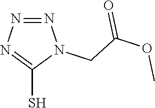 |
| A-13 | 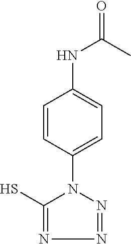 [SMILES: CC(=O)Nc1ccc(-n2nnnc2S)cc1] |
| A-14 | 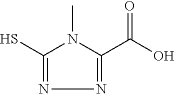 |
| A-15 | 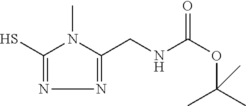 [SMILES: Cn1c(S)nnc1CNC(=O)OC(C)(C)C] |
| A-16 | 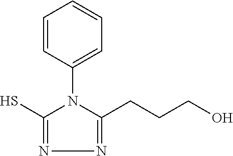 [SMILES: OCCCc1nnc(S)n1-c1ccccc1] |

The dispersion-stabilizing compound is preferably selected from the group consisting of N,N-dibutyl-(2,5-dihydro-5-thioxo-1H-tetrazol-1-yl-acetamide, 5-heptyl-2-mercapto-1,3,4-oxadiazole, 1-phenyl-5-mercaptotetrazol, 5-methyl-1,2,4-triazolo-(1,5-a) primidine-7-ol, and S-[5-[(ethoxycarbonyl)amino]-1,3,4-thiadiazol-2-yl] O-ethyl thiocarbonate.

The dispersion-stabilizing compounds according to Formulae I to IV are preferably non-polymeric compounds. Non-polymeric compounds as used herein means compounds having a Molecular Weight which is less preferably than 1000, more preferably less than 500, most preferably less than 350.

The amount of dispersion-stabilizing compound, expressed as wt % relative to the total weight of silver in the silver ink, is preferably from 0.05 to 10, more preferably from 0.1 to 7.5, most preferably from 0.15 to 5 wt %

When the amount of the dispersion-stabilizing compound relative to the total weight of silver is too low, the stabilizing effect may be too low, while a too high amount of the dispersion-stabilizing compound may adversely affect the conductivity of the coating or patterns obtained with the silver ink.

### Polymeric Dispersant

The silver composition may contain a polymeric dispersant.

Polymeric dispersants typically contain in one part of the molecule so-called anchor groups, which adsorb onto the silver particles to be dispersed. In another part of the molecule, polymeric dispersants have polymer chains compatible with the dispersion medium, also referred to as liquid vehicle, and all the ingredients present in the final printing or coating fluids.

Polymeric dispersants are typically homo- or copolymers prepared from acrylic acid, methacrylic acid, vinyl pyrrolidinone, vinyl butyral, vinyl acetate or vinyl alcohol monomers.

The polymeric dispersants disclosed in EP-A 2468827, having a 95 wt % decomposition at a temperature below 300° C. as measured by Thermal Gravimetric Analysis may also be used.

However, in a preferred embodiment metallic nanoparticle dispersion comprises less than 5 wt % of a polymeric dispersant relative to the total weight of the dispersion, more preferably less than 1 wt %, most preferably less than 0.1 wt %. In a particularly preferred embodiment the dispersion comprises no polymeric dispersant at all.

It has been observed that the presence of a polymeric dispersant may negatively influence the sintering efficiency.

### Liquid Carrier

The silver composition preferably comprises a liquid carrier.

The liquid carrier is preferably an organic solvent. The organic solvent may be selected from alcohols, aromatic hydrocarbons, ketones, esters, aliphatic hydrocarbons, higher fatty acids, carbitols, cellosolves, and higher fatty acid esters.

Suitable alcohols include methanol, ethanol, propanol, 1-butanol, 1-pentanol, 2-butanol, t-butanol.

Suitable aromatic hydrocarbons include toluene and xylene.

Suitable ketones include methyl ethyl ketone, methyl isobutyl ketone, 2,4-pentanedione and hexa-fluoroacetone.

Also glycol, glycolethers, N,N-dimethyl-acetamide, N,N-dimethylformamide may be used.

A mixture of organic solvents may be used to optimize the properties of the metallic nanoparticle dispersion.

Preferred organic solvents are high boiling solvents. High boiling organic solvents referred to herein are solvents which have a boiling point that is higher than the boiling point of water (>100° C.).

Preferred high boiling solvents are shown in Table 2.

TABLE 2

| Chemical formula | Chemical name | Bp (° C.) |
|---|---|---|
| 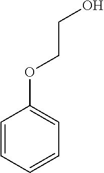 | 2-phenoxy ethanol (ethylene glycol monophenylether) | 247 |
| 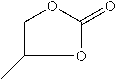 | 4-methyl-1,3-dioxolan-2-one (propylene carbonate) | 242 |
| 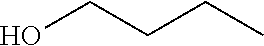 | n-butanol | 117 |
| 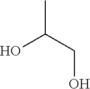 | 1,2-propanediol | 211-217 |
| 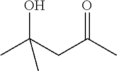 | 4-hydroxy-4-methylpentan-2-one (diacetone alcohol) | 168 |
| 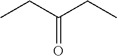 | Pentan-3-one (diethyl ketone) | 102 |
| 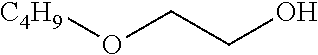 | 2-Butoxyethanol Ethylene glycol monobutyl ether | 171 |
| 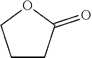 | Dihydrofuran-2(3H)-one (Gamma-butyrolacton) | 204 |
| 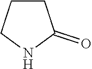 | 2-pyrrolidone | 245 |
| 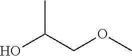 | 1-methoxy-2-propanol (propyleneglycolmonomethylether | 120 |

Particularly preferred high boiling solvents are 2-phenoxy ethanol, propylene carbonate, propylene glycol, n-butanol, 2-pyrrolidone and mixtures thereof.

The silver ink preferably comprises at least 25 wt % of 2-phenoxyethanol, more preferably at least 40 wt %, based on the total weight of the silver ink.

### Additives

To optimize its properties, and also depending on the application for which it is used, additives such as reducing agents, wetting/levelling agents, dewetting agents, rheology modifiers, adhesion agents, tackifiers, humectants, jetting agents, curing agents, biocides or antioxidants may be added to the silver composition described above.

The silver composition may comprise a surfactant. Preferred surfactants are Byk® 410 and 411, both solutions of a modified urea, and Byk® 430, a solution of a high molecular urea modified medium polar polyamide.

The amount of the surfactants is preferably between 0.01 and 10 wt %, more preferably between 0.05 and 5 wt %, most preferably between 0.1 and 0.5 wt %, relative to the total amount of the silver ink.

It may be advantageous to add a small amount of a metal of an inorganic acid or a compound capable of generating such an acid to the silver composition as disclosed in EP-A 2821164. Higher conductivities were observed of layers or patterns formed from such silver compositions.

Higher conductivities may also be obtained when silver compositions containing a compound according to Formula X, as disclosed in EP-A 3016763.

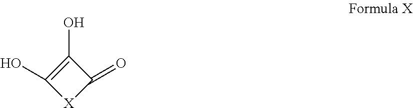

wherein
X represents the necessary atoms to form a substituted or unsubstituted ring.

A particularly preferred compound according to Formula X is an ascorbic or erythorbic acid derivative compound.

### Substrate

The substrate is an optical transparent substrate and may be a glass or a polymeric substrates.

Preferred polymeric substrates include for example polycarbonate, polyacrylate, polyethylene terephthalate, polyethylene, polypropylene, polyvinylchloride, or polyvinylidene.

Preferred polymeric substrates are polycarbonate, polyethylene terephthalate (PET) or polyvinylchloride (PVC) based substrates. A particular preferred substrate is a PET substrate.

Optical transparent substrates are commercially available, for example COSMOSHINE® substrates from Toyobo or ELECROM™ substrates from Policrom.

### Applications

Transparent conductive films are an important component in a number of electronic devices including liquid-crystal displays, OLEDs, touchscreens and photovoltaics.

### EXAMPLES

### Materials

All materials used in the following examples were readily available from standard sources such as ALDRICH CHEMICAL Co. (Belgium) and ACROS (Belgium) unless otherwise specified. The water used was deionized water.

A-01 is the dispersion-stabilizing compound N-dibutyl-(2,5-dihydro-5-thioxo-1H-tetrazol-1-yl)acetamide (CASRN168612-06-4) commercially available from Chemosyntha.

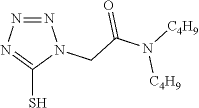

A-17 is a polyalkylene carbonate diol commercially available under the name DURANOL™ G3450J from Kowa Amerian Corp.

A-001 is a 1000 Mw polycarbonate diol commercially available under the name Converge Polyol 212-10 from Aramco Performance Materials.

PhenEth-01 is a 10 wt % solution of phenoxyethanol in 2-pyrrolidone.

PhenEth-02 is a 50 wt % solution of phenoxyethanol in 2-pyrrolidone.

PhenEth-03 is a 70 wt % solution of phenoxyethanol in 2-pyrrolidone.

Mask-01 is a mask prepared from a Powercoat® HD substrate (available from Arjowiggins Creative Papers) as described below.

### Measurements Methods

### Conductivity of the Silver Coatings

The surface resistance (SER) of the silver coatings was measured using a four-point collinear probe. The surface or sheet resistance was calculated by the following formula:

SER=(π/ln2)*(V/I)

wherein

SER is the surface resistance of the layer expressed in Ω/square;

π is a mathematical constant, approximately equal to 3.14;

ln2 is a mathematical constant equal to the natural logarithmic of value 2, approximately equal to 0.693;

V is voltage measured by voltmeter of the four-point probe measurement device;

I is the source current measured by the four-point probe measurement device.

For each sample, six measurements were performed at different positions of the coating and the average value was calculated.

The silver content MA_{g} (g/m²) of the coatings was determined by WD-XRF.

The conductivity of the coated layers was then determined by calculating the conductivity as a percentage of the bulk conductivity of silver using the following formula:

$$\% {Ag}_{( bulk )} = \frac{{σ}_{Coat}}{{σ}_{A g}} \times 100$$

$$\% {Ag}_{( bulk )} = \frac{{ρ}_{A g}}{{σ}_{A g} \times S E R \times {M}_{A g}} \times 100$$

wherein σ_{Ag} the specific conductivity of silver (equal to 6.3×10⁷S/m), σ_{coat} is the specific conductivity of the Ag coating and ρ_{Ag} is the density of silver (1.049×10⁷ g/m³).

### Preparation of a Mask

FIG. 2 schematically represent a mask used in the examples to pattern a silver coating.

To prepare mask-01, rectangles having a height (120) of 10 mm and a varying width (110a to 110d) were cut out with a scalpel from a Powercoat® HD substrate (100). The widths are respectively 5, 2, 1 and 0.5 mm.

### Determination of the Amount of Silver

The silver amount in the exposed and non-exposed areas was determined using Wave Dispersing X-Ray Fluorescence (WDXRF) using an Axios mAX instrument (available from Malvern)

### Example 1

A layer of the silver inkjet ink SI-J20x (commercially available from Agfa Gevaert) was coated on an optically transparent substrate (COSMOSHINE® A4300) commercially available from Toyobo) by blade coating (wet thickness was 10 μm) and then dried in an oven using the conditions shown in Table 3.

The dried coatings were then patterned using a NIR lamp (ADPHOS) and mask-01.

After exposure, the mask was removed and the exposed and non-exposed areas of the coating were wiped using a clean room type tissue wetted with the solvents shown in Table 3.

The amount of silver that has been removed in the cleaning step in both exposed and unexposed areas were measured and are given in Table 3.

TABLE 3

| | | | | Removal | Removal | |
|---|---|---|---|---|---|---|
| | | NIR | | unexposed | exposed | |
| | Drying | sintering | Cleaning | area (%) | area (%) | # wipes |
| SC-01 | 15 min@60° C. | — | — | | | Not |
| | | | | | | dried |
| SC-02 | 20 min@60° C. | 70 mm/s | PhenEth-01 | 100 | 45 | |
| SC-03 | 20 min@60° C. | 70 mm/s | PhenEth-02 | 100 | 20 | >80 |
| SC-04 | 20 min@60° C. | 100 mm/s | PhenEth-03 | 90 | 25 | >80 |
| SC-05 | 20 min@60° C. | 20 mm/s | PhenEth-02 | 100 | 30 | 50 |
| SC-06 | 20 min@60° C. | 50 mm/s | PhenEth-02 | 100 | 30 | 41 |
| SC-07 | 20 min@60° C. | 100 mm/s | PhenEth-02 | 100 | 0 | 17 |
| SC-08 | 20 min@60° C. | 100 mm/s | PhenEth-02 | 100 | 0 | 18 |

From Table 3 it is clear that after NIR exposure, the exposed areas are not affected in the cleaning step while silver in the unexposed areas are more or less removed in the cleaning step.

The silver pattern obtained after NIR patterning and the cleaning step of the silver coating SC-07 has been subjected to a thermal treatment of 30 minutes at 150° C.

A Surface Resistance of 0.246 ohm/square and a bulk conductivity of 23.8% was obtained in the exposed areas.

### Example 2

The silver coatings SC-09 to SC-18 were prepared as described in example but now on a Elecrom STS H.02-H.02 substrate (available from POLICROM SCREENS).

The conditions used for drying, NIR patterning and cleaning are given in Table 4.

TABLE 4

| | | | | Removal | Removal | |
|---|---|---|---|---|---|---|
| | | NIR | | unexposed | exposed | |
| | Drying | sintering | Cleaning | area (%) | area (%) | # wipes |
| SC-09 | 15 min@60° C. | — | — | | | Not |
| | | | | | | dried |
| SC-10 | 30 min@60° C. | 70 mm/s | Water | 5 | 0 | 30 |
| SC-11 | 20 min@60° C. | 20 mm/s | Water | 0 | 0 | 10 |
| SC-12 | 20 min@60° C. | 20 mm/s | Propylene | 100 | 90 | 2 |
| | | | Carbonate | | | |
| SC-13 | 20 min@60° C. | 20 mm/s | Dry Tissue | 10 | 40 | 7 |
| SC-14 | 20 min@60° C. | 100 mm/s | Water | 100 | 90 | 8 |
| SC-15 | 20 min@60° C. | 100 mm/s | Dry Tissue | 10 | 10 | 8 |
| SC-16 | 20 min@60° C. | 70 mm/s | Water | 90 | 90 | 60 |
| SC-17 | 20 min@60° C. | 70 mm/s | Soapy water | 100 | 10 | 68 |
| SC-18 | 20 min@60° C. | 70 mm/s | Dry Tissue | 75 | 0 | 20 |

From Table 4 it is clear that after NIR exposure, the exposed areas are not affected in the cleaning step while silver in the unexposed areas are more or less removed in the cleaning step

The surface resistance in the exposed areas of SC-17 and SC-10 was respectively 2.114 and 0.893 ohm/square; the bulk conductivity respectively 2.5 and 5.3%.

1-15. (canceled)

16. A method of preparing a transparent conductive film, the method comprising:
applying a silver composition on a substrate thereby forming a silver coating on the substrate,
imagewise exposing the silver coating with Near Infrared (NIR) radiation thereby forming exposed and non-exposed areas, and
removing the non-exposed areas of the silver coating.

17. The method of claim 16, wherein the imagewise exposure is carried out through a mask.

18. The method of claim 16, further comprising a drying step wherein the silver coating is dried before imagewise exposing it to NIR radiation.

19. The method of claim 18, wherein the drying step is carried out during 15 to 30 minutes at a temperature between 40° C. and 100° C.

20. The method of claim 16, further comprising a thermal treatment after removing the non-exposed areas of the silver coating.

21. The method of claim 20, wherein the thermal treatment is carried out during 15 to 60 minutes at a temperature between 130° C. and 180° C.

22. The method of claim 20, wherein the thermal treatment is carried out at a relative humidity of at least 50% at a temperature of at least 50° C.

23. The method of claim 16, wherein the non-exposed areas are removed with a solvent.

24. The method of claim 23, wherein the solvent is selected from water, propylene carbonate, and a phenoxyethanol/2-pyrolidone mixture.

25. The method of claim 16, wherein the substrate is an optical transparent substrate.

26. The method of claim 25, wherein the optical transparent substrate is a polyethyleneterephthalate (PET) based substrate.

27. The method of claim 16, wherein the silver composition comprises silver nano-particles.

28. The method of claim 27, wherein the silver composition comprises a dispersion-stabilizing compound (DSC) having a chemical structure according to Formulae I to IV, 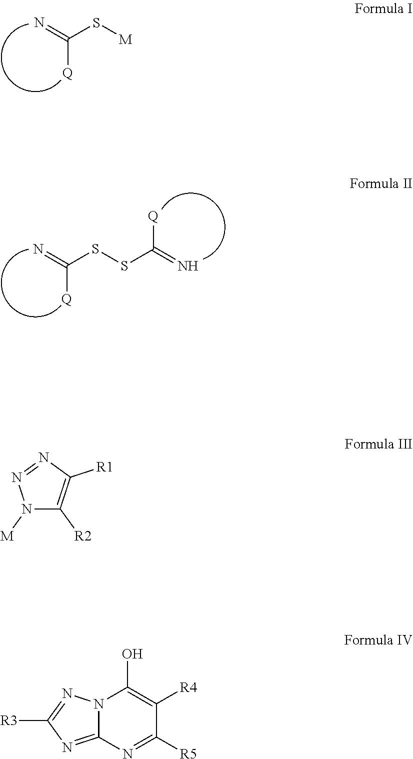
wherein
Q represents the necessary atoms to form a substituted or unsubstituted five or six membered heteroaromatic ring;
M is selected from the group consisting of hydrogen, a monovalent cationic group, and an acyl group;
R1 and R2 are each independently selected from the group consisting of a hydrogen, a substituted or unsubstituted alkyl group, a substituted or unsubstituted alkenyl group, a substituted or unsubstituted alkynyl group, a substituted or unsubstituted alkaryl group, a substituted or unsubstituted aralkyl group, a substituted or unsubstituted aryl or heteroaryl group, a hydroxyl group, a thioether, an ether, an ester, an amide, an amine, a halogen, a ketone, and an aldehyde, or R1 and R2 may represent the necessary atoms to form a five to seven membered ring; and
R3 to R5 are each independently selected from the group consisting of a hydrogen, a substituted or unsubstituted alkyl group, a substituted or unsubstituted alkenyl group, a substituted or unsubstituted alkynyl group, a substituted or unsubstituted alkaryl group, a substituted or unsubstituted aralkyl group, a substituted or unsubstituted aryl or heteroaryl group, a hydroxyl group, a thiol, a thioether, a sulfone, a sulfoxide, an ether, an ester, an amide, an amine, a halogen, a ketone, an aldehyde, a nitrile, and a nitro group, or R4 and R5 may represent the necessary atoms to form a five to seven membered ring.

29. The method of claim 28, wherein the DSC has a chemical structure according to Formula I 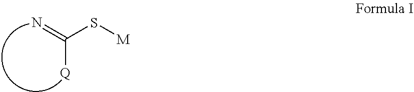
wherein
M is selected from the group consisting of hydrogen, a monovalent cationic group, and an acyl group and
Q represents the necessary atoms to form a five membered heteroaromatic ring.

30. The method of claim 16, wherein the silver composition comprises a liquid carrier selected from the group consisting of 2-phenoxy ethanol, propylene carbonate, propylene glycol, n-butanol, and 2-pyrrolidone.
